(19) United States
(12) Patent Application Publication
(10) Pub. No.: US 2014/0224317 A1
(43) Pub. Date: Aug. 14, 2014

(54) OPTOELECTRONIC DEVICES WITH THIN BARRIER FILMS WITH CRYSTALLINE CHARACTERISTICS THAT ARE CONFORMALLY COATED ONTO COMPLEX SURFACES TO PROVIDE PROTECTION AGAINST MOISTURE

(71) Applicants: Rebekah K. Feist, Midland, MI (US); Banu Tosun, Minneapolis, MN (US); Stephen A. Campbell, Arden Hills, MN (US); Eray Aydill, Hopkins, MN (US)

(72) Inventors: Rebekah K. Feist, Midland, MI (US); Banu Tosun, Minneapolis, MN (US); Stephen A. Campbell, Arden Hills, MN (US); Eray Aydill, Hopkins, MN (US)

(73) Assignees: REGENTS OF THE UNIVERSITE OF MINNESOTA, St. Paul, MN (US); DOW GLOBAL TECHNOLOGIES LLC, Midland, MI (US)

(21) Appl. No.: 14/236,404

(22) PCT Filed: Jul. 27, 2012
(86) PCT No.: PCT/US12/48516

§ 371 Date: Jan. 31, 2014

Related U.S. Application Data
(60) Provisional application No. 61/514,133, filed on Aug. 2, 2011.

(51) Int. Cl. H01L 31/0216; H01L 23/00; H01L 31/18

(52) U.S. Cl. CPC H01L 31/02167; H01L 31/18; H01L 23/564
USPC 136/256; 438/93

(57) ABSTRACT

The present invention provides optoelectronic devices containing at least one conforming, thin film barrier coating provided on a nonplanar surface comprising a plurality of junctures. The barrier coating has a hybrid morphology including crystalline domains distributed in an amorphous matrix. The conformal coatings protect the optoelectronic device with long-lasting, durable, high quality barrier protection even though the coatings have sufficient crystalline characteristics so that many embodiments are electrically conductive.

### PRIORITY

The present patent application claims priority from U.S. Provisional patent application having Ser. No. 61/514,133, filed on Aug. 2, 2011, by Feist et al. and entitled OPTOELECTRONIC DEVICES WITH THIN BARRIER FILMS WITH CRYSTALLINE CHARACTERISTICS THAT ARE CONFORMALLY COATED ONTO COMPLEX SURFACES TO PROVIDE PROTECTION AGAINST MOISTURE, wherein the entirety of said provisional patent application is incorporated herein by reference.

### FIELD OF THE INVENTION

The present invention relates to optoelectronic devices containing at least one thin film barrier coating with crystalline characteristics that is conformally coated onto a surface comprising a plurality of junctures. More specifically, the conformal barrier coating comprises one or more inorganic materials having a hybrid morphology including crystalline domains distributed within an amorphous matrix.

### BACKGROUND OF THE INVENTION

Both n-type chalcogenide materials and/or p-type chalcogenide materials have photoelectric functionality (also referred to as photoabsorbing or photovoltaic functionality). These materials absorb incident light and generate an electric output when incorporated into an optoelectronic device. Consequently, these chalcogenide-based photoelectrically active materials have been used as the photovoltaic absorber region in functioning photovoltaic devices. Illustrative p-type chalcogenide materials often include selenides (S), sulfides (also referred to as S; in some embodiments, SS indicates that sulfur is being used in combination with selenium), and/or tellurides (Te or sometimes informally just T in this context) of at least one or more of copper (C), indium (I), gallium (G), and/or aluminum (Al or sometimes informally just A in this context). Specific chalcogenide compositions may be referred to by acronyms such as CIS, CISS, CIGS, CIGST, CIGSAT, and/or CIGSS compositions, or the like, to represent the constituents of the composition. Hereinafter, unless otherwise expressly stated, the term “CIGS material” shall refer generally to a photoelectrically active composition including at least one of S, Se, and/or Te and two or more metals including at least copper and indium.

Photoabsorbers based upon chalcogenide compositions offer several advantages. As one advantage, these compositions tend to have a very high cross-section for absorbing incident light. This means that a very high percentage of incident light can be captured by chalcogenide-based absorber layers that are very thin. For example, in many devices, chalcogenide-based absorber layers have a thickness in the range of from about 1 μm to about 2 μm. These thin layers allow devices incorporating these layers to be flexible. This is in contrast to crystalline silicon-based absorbers. Crystalline silicon-based absorbers have a lower cross-section for light capture and generally must be much thicker to capture the same amount of incident light. Crystalline silicon-based absorbers tend to be rigid, not flexible.

Although thin film solar cells incorporating CIGS materials such as copper indium gallium diselenide thin have demonstrated laboratory efficiencies exceeding 20%, these high efficiencies may degrade with time as the devices are exposed to water or water vapor. For example, it is well known that water can diffuse to a CIGS—CdS—ZnO heterojunction and degrade the performance of the corresponding device. This penetration must be reduced or stopped to increase solar cell lifetime. Other kinds of optoelectronic devices based on other kinds of absorbers also may include components that are vulnerable to moisture degradation. Accordingly strategies to protect against moisture are strongly desired in the optoelectronic industry.

### SUMMARY OF THE INVENTION

The present invention relates to optoelectronic devices containing at least one thin film barrier coating with crystalline characteristics, wherein the barrier coating is conformally coated onto a surface comprising a plurality of junctures, and wherein the coating topography mimics the topography of the surface. The barrier provides excellent protection against moisture. The present invention is based at least in part upon the discovery that inorganic compositions having a hybrid morphology are able to form such thin film, conformal coatings on such complex surfaces with long-lasting, durable, high quality barrier protection even though the coatings have sufficient crystalline characteristics so that many embodiments are electrically conductive. The ability of these thin, conformal coatings to work so well on complex surfaces is surprising. In the past, thin, conformal polycrystalline films have tended to suffer from cracking and other serious defects when formed on complex surfaces, particularly at surface junctures. The conventional expectation is that such thin, conformal, crystalline coatings would have a too short service life (if any). Amorphous films also are problematic as well, since amorphous films tend to have higher electrical resistance and many small defects that allow contaminant diffusion.

The coatings of the present invention advantageously provide an excellent barrier against water and water vapor (collectively referred to herein as moisture) even for embodiments having a thickness on the order of about 2 micrometers or less, even about 1 micrometer or less, an even on the order of about 100 nm to 200 nm. The ability of films of such modest thickness and crystalline content to provide such a high degree of moisture protection is quite unexpected but very beneficial, particularly in embodiments that also possess high levels of electrical conductivity.

In many embodiments, the compositions may be provided in the form of conductive thin films having a high degree of visible light transmittance to allow light to pass through to reach underlying absorber layer(s). This makes the barrier films very useful in photovoltaic devices, although the barrier coatings are useful to provide protection for optoelectronic devices of all kinds. The compositions optionally may be used in combination with one or more other barrier strategies for enhanced protection.

The coatings of the invention are easy to manufacture and are compatible with a wide range of fabrication techniques for a wide range of optoelectronic devices. For example, the protection strategies of the present invention may be adapted for continuous (e.g., roll to roll) and/or batch manufacturing of optoelectronic devices.

In one aspect, the present invention relates to an optoelectronic device comprising:
a surface having a topography such that at least first and second plane portions of the surface meet at one or more junctures; and
a conformal barrier coating provided on the surface in a manner effective to conform to said plane portions and said juncture, wherein the barrier coating has a hybrid morphology that comprises inorganic, crystalline domains embedded in an inorganic amorphous matrix.

In another aspect, the present invention relates to a method of providing electricity, comprising the steps of:
providing an optoelectronic device according to any preceding device claim; and
using the device in a manner effective to convert incident light energy into electric energy.

In another aspect, the present invention relates to a method of making an optoelectronic device, comprising the steps of:
providing an optoelectronic substrate comprising an absorber region, at least first and second electrode layers electrically coupled to the absorber region wherein at least the first electrode layer is at least partially transparent to visible light, and an electronic grid electrically coupled to the first electrode layer, and wherein the first electrode layer and the electronic grid define a surface comprising a plurality of junctures;
forming a conforming inorganic, barrier coating on the surface, wherein the barrier coating has a hybrid morphology that comprises inorganic, crystalline domains embedded in an inorganic amorphous matrix.

### BRIEF DESCRIPTION OF THE DRAWINGS

The above mentioned and other advantages of the present invention, and the manner of attaining them, will become more apparent and the invention itself will be better understood by reference to the following description of the embodiments of the invention taken in conjunction with the accompanying drawings, wherein:

FIG. 1(a) schematically illustrates the structure of a solar cell.

FIG. 1(b) schematically illustrates a first embodiment showing how a barrier film is incorporated into the solar cell of FIG. 1a.

FIG. 2(a) shows the solar cell stability performance for the solar cell configuration shown in FIG. 1(b). The efficiencies are normalized with respect to the initial solar cell efficiencies and ranked from left to right based on their performance after 216 hours in the damp heat test chamber.

FIG. 2(b) shows the absolute values of the solar cell efficiencies for the solar cells in tested in FIG. 2(a).

FIG. 3 shows a low magnification and high magnification TEM images of SnO2 films having a hybrid morphology. The films are deposited on a SiO₂-coated Si substrate at room temperature using 150 W RF power. The inset is the diffraction pattern from the SnO₂ film confirming the semicrystalline structure of the film.

FIG. 4 show (a) Efficiency (η), (b) fill factor (FF), (c) open circuit voltage (V_{oc}), (d) short circuit current density (J_{sc}), (e) series resistance (Rₛᵣ) and (f) shunt resistance (Rₛₕ) of control solar cells as a function of damp-heat exposure time (DHT).

FIG. 5 shows temporal evolution of the current-voltage characteristic of an uncoated control CIGS solar cell as a function of damp heat exposure time.

### DETAILED DESCRIPTION OF PRESENTLY PREFERRED EMBODIMENTS

The embodiments of the present invention described below are illustrative and are not intended to be exhaustive or to limit the invention to the precise forms disclosed in the following detailed description. Rather the embodiments are chosen and described so that others skilled in the art may appreciate and understand the principles and practices of the present invention.

Inorganic compositions of the present invention a hybrid morphology and provide an excellent barrier to protect a wide range of optoelectronic devices against intrusion. The term “inorganic” generally means that a major portion, e.g., at least 50 weight percent of the composition excluding solvent(s), is formed from material(s) of a mineral origin rather than an organic origin. The term “organic” generally refers to materials having a biological origin such as compounds that include at least one carbon atom that is covalently bonded to at least one other type of atom with the proviso that if the carbon is bonded to an oxygen, the carbon also is bonded to at least one other type of atom. In preferred embodiments, inorganic materials include at least 70, more preferably at least 85, more preferably at least 95, and even more preferably 100 weight percent of material(s) of a mineral origin. Inorganic materials may be compounds, salts, and/or the like.

In many embodiments, inorganic material(s) useful in the practice of the present invention include ceramic material(s) such as one or more oxides, carbides, and/or nitrides of one or more metals. Some embodiments may incorporate combinations of oxide(s), carbide(s), and/or nitride(s). An example of such a combination is an oxynitride. Exemplary metals include Sn, In, Zn, Si, Al, Ti, Cu, Ce, Ta, Zr, combinations of these, and the like. Preferred embodiments include oxides such as SnO₂, fluorine-doped SnO₂, indium tin oxide, fluorine-doped ZnO, zinc stannate (Zn₂SnO₄), Cd stannate (Cd₂SnO₄), combinations of these, and the like.

In addition to such ceramic constituents, the inorganic material(s) suitable in the practice of the present invention optionally may include one or more dopants such as F, Zn, Sn, Cd, Ge, combinations of these, and the like.

The barrier coatings of the present invention have a hybrid morphology comprising an amorphous phase and a crystalline phase, wherein at least a major portion of the amorphous phase constitutes an amorphous matrix and at least a major portion of the crystalline phase comprises crystalline grains (also referred to herein as domains) embedded within the amorphous matrix. As used herein, the term “major portion” with respect to the amorphous or crystalline phase means at least 30 volume percent, preferably at least 50 volume percent, more preferably at least 80 volume percent, and even up to substantially 100 volume percent of the phase has the recited characteristic. In more preferred embodiments, the barrier coatings have a volume percent ratio of amorphous content to crystalline content in the range from 1:2 to 100:1, preferably 1.5:1 to 20:1, more preferably 2:1 to 10:1. In an exemplary embodiment, a coating including about 70 to 75 volume percent of amorphous content and 25 to 30 volume percent of crystalline domains. Desirably, the crystalline content is less than the percolation threshold so that a major portion of the crystalline domains are spaced apart to substantially avoid continuous networks of crystalline domains that have a length sufficient to span the film thickness in some embodiments, or even 75% of the film thickness in some embodiments, or even 50% of the film thickness in some embodiments.

Advantageously, coatings having this morphology have excellent barrier properties against moisture and yet may be strongly electrically conductive. Without wishing to be bound by theory, it is believed that the amorphous matrix and distribution of discrete crystalline grain boundaries help impart moisture resistance throughout the bulk of the coatings and not merely at the interface between the coating and adjacent features. Generally, moisture is able to gain egress through a coating having crystalline characteristics along crystalline grain boundaries. In a coating that is substantially all crystalline, grain boundaries may extend generally continuously through a film from one major face to the other. Consequently, crystalline coatings are not sufficiently effective barriers against moisture intrusion. In contrast, when substantial portions of a crystalline phase are dispersed as domains or grains within an amorphous matrix, substantial portions of the crystalline grain boundaries are more discontinuous. The amorphous matrix isolates the crystalline domains to prevent moisture from moving through the coating. The amorphous matrix and lack of continuous crystalline grain boundaries thereby impart moisture resistance. In the meantime, the crystalline domains impart electrical conductivity. The ability of the coatings to protect against moisture while still providing high levels of electrical conductivity is an unexpected result of the hybrid composition, particularly in nanoscale, thin film embodiments in which the film thickness is on the order of 2000 nm or less.

For example, in one set of tests, the protection abilities of SnO₂ films of the present invention having thicknesses of about 200 nm to 500 nm were evaluated. This was done by comparing the performance of CIGS solar cells protected by the films against otherwise identical, but unprotected CIGS cells. The CIGS cells had an initial efficiency in the range from 8% to 12%. The SnO₂ films of the present invention were formed over the collection grid of the cells under conditions such that the films had a hybrid morphology including amorphous and crystalline phases per TEM analysis. The crystalline phases were discontinuous and generally homogeneously (i.e., generally distributed throughout) but non-uniformly (e.g., with a substantially random orientation) dispersed and embedded as domains within the amorphous phase. The hybrid morphology was accomplished by depositing the protective films at room temperature by radio frequency magnetron sputtering at suitably low power levels. The deposition used SnO₂ targets and occurred at 5 mTorr operating pressure in a chamber atmosphere predominately comprising a flow of 100% Argon gas. Performance in accelerated damp heat tests was evaluated. The protected solar cells showed minor loss of efficiency even after being aged for 240 hours at 85° C. and 85% relative humidity. In comparison, the unprotected cells lost nearly 80% of their initial efficiency after only 24 hours aging under the same conditions.

Without wishing to be bound by theory, these results suggest that the thin (nanometer scale thickness), hybrid coatings of the invention function as exceptional moisture barriers to significantly increase device lifetime. The substantially unimpaired ability to electrically couple to the grid of the cells through the overlying thin coating shows that the coatings of this embodiment also have excellent electrical conductivity.

The performance of the protected cells of the present invention also was compared to the performance of solar cells protected by substantially fully crystalline SnO₂ films of comparable thickness. The more crystalline SnO₂ films were formed by depositing the SnO₂ at a higher temperature of about 150° C. The hybrid coatings of the present invention were fabricated at low power (100 W), while higher power (250 W) conditions in combination with the higher temperature resulted in more crystalline films. The more crystalline films had a thickness of about 200 nm to 500 nm.

The coatings of the present invention having a hybrid amorphous/crystalline morphology dramatically outperformed the crystalline coatings. As noted above, cells protected by the hybrid films of the present invention retained substantially the entirety of their efficiency characteristics even after aging for 240 hours. In contrast, the cells protected by the crystalline films lost 59% of their initial efficiency after being aged at 85° C. and 85% relative humidity for 216 hours. Without wishing to be bound by theory, these results strongly support the hypothesis that the hybrid morphology of the barrier films of the present invention contributes to their excellent moisture protection. It is believed that the distribution of crystalline grain boundaries within the bulk of the hybrid film contribute to barrier properties that resist moisture intrusion. The principles of the present invention thus are advantageously practiced with any optoelectronic device for which moisture resilience is desired.

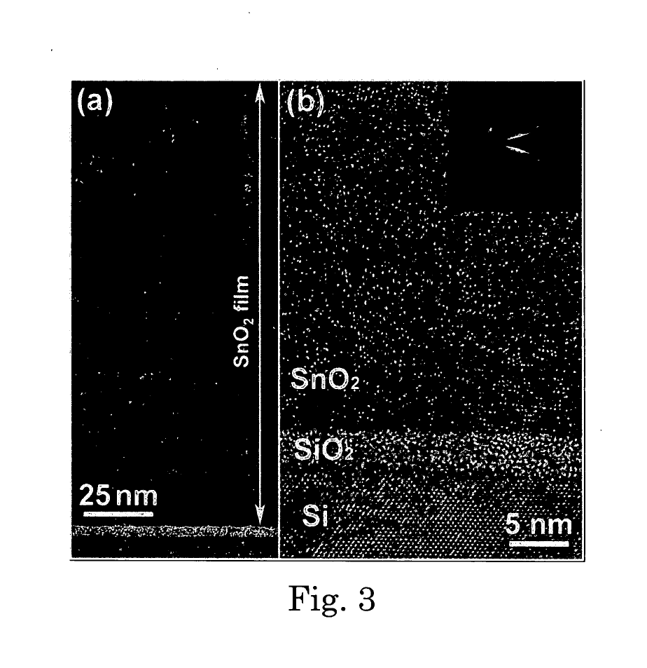

TEM analysis and/or Bragg diffraction analysis can be used to assess the amorphous and/or crystalline characteristics of a film according to techniques well known in the industry. For example, transmission electron microscopy (TEM) analysis may be conducted using an FEI Tecnai F-30 microscope with a Schottky field-emission electron gun operated at 300 keV. The technical article M. J. Behr, K. A. Mkhoyan, and E. S. Aydil, ACS Nano 4 (2010) 5087 provides illustrative methods to evaluate amorphous and crystalline characteristics. These techniques can be interpreted to qualitatively and quantitatively assess the amorphous and crystalline characteristics. The entirety of this technical article is incorporated herein by reference for all purposes. Exemplary results of TEM analysis and Bragg diffraction are described further below in connection with FIG. 3.

The crystalline domains can be distributed throughout the barrier films in a variety of ways. In some embodiments, the films are formed under conditions such that the crystalline domains are distributed generally homogeneously throughout the bulk volume of the films but with a non-uniform random orientation as a whole even if small portions of the bulk volume might have some order locally. In other embodiments, the films can be formed so that the crystalline grain distribution is heterogeneous throughout the bulk volume of the films.

For instance, films could be formed in which the film portions proximal to the major faces of the film are predominantly amorphous while the crystalline domains are distributed within the interior regions of the film distal from the major faces. In other embodiments, the distribution of the crystalline grains can be otherwise graded laterally or vertically within the form. For an exemplary graded film, a portion of the film relatively proximal to the light incident face of the film could be relatively rich in the amorphous phase with little if any crystalline content, while other portions adjacent an underlying element, e.g., an electric grid or a transparent electrode layer, can be relatively rich in the crystalline domains.

Deposition conditions, described further below, can be used to control crystalline grain distribution and content. For instance, a portion of a film can be deposited under conditions that favor more amorphous content while other portions can be deposited under conditions that favor increased content of the crystalline domains. Deposition conditions also can be varied to deposit a multilayer stack comprising a plurality of barrier films of the present invention, wherein the crystalline content can be varied so that some layers include relatively more amorphous content while other layers include relatively more crystalline domain content. As another option, two or more sources can be co-deposited to tune the composition. As still another option, the power of a sputtering gun can be varied to favor amorphous deposition in some time period(s) and crystalline domains in other time period(s).

FIG. 3 shows a TEM image and a Bragg diffraction for a hybrid film of the present invention. The hybrid film shown in FIG. 3 comprises crystalline domains with a fairly narrow size distribution in the range from 2 nm to 10 nm. The domains do not necessarily need to be uniform in size. In, some embodiments, a broader Gaussian distribution, or even a polymodal or other kind of size distribution may be present.

FIG. 3 also shows an illustrative embodiment in which the crystalline fraction is estimated to be between 25-30% of the film volume. An amorphous matrix generally provides the remaining content of the film volume. Although this is the fraction in this film, it is likely that other film embodiments could include greater or less crystalline content. Adjusting the crystalline content provides a means of tuning the transmittance and electrical conductivity and barrier properties of the film. Techniques for doing this are described further below.

It is desirable in some modes of practice that the barrier films possess low resistivity so that the films are sufficiently electrically conductive to provide protective coatings over electrical contacts, such as electric grids are transparent conducting layers, without unduly hindering electric coupling to such contacts. Exemplary embodiments with excellent electric conductivity may have a low resistivity of about 10⁻¹ Ohm-cm or less, preferably 10⁻⁴ Ohm-cm or less, more preferably 10-5 Ohm-cm or less, even more preferably 10⁻⁶ Ohm-cm or less. In some embodiments resistivity is no lower than 10⁻⁸ Ohm-cm or even 10⁻⁷ Ohm-cm.

For photovoltaic applications in which the barrier films for which the films are positioned between the absorbing layer(s) and the light incident face of the devices, the barrier films desirably are transparent with respect to light having a wavelength in the range from 300 nm to 1400 nm. An exemplary embodiment of a barrier film is sufficiently transparent to visible light such that the film light transmittance from 300 nm to 1400 nm prior to aging is at least 70%, preferably higher than 85%, more preferably higher than 90%, and even more preferably at least about 95%. Light transmittance is measured using a BYK Gardner (Haze-Gard Plus) instrument according to the ASTM D-1003D-07 wherein the measured transmittance is the total transmittance obtained by the method in the range from 300 nm to 1400 nm at room temperature. A suitable value for light transmittance is obtained from an average of three measurements.

Barrier films may have thicknesses over a wide range. If a film is too thin, the film may not provide a desired degree of moisture protection. Additionally, they may be too resistive for a desired use. On the other hand, films that are too thick might have lower visible light transmittance than is desired. Additionally and counter intuitively, thicker films may have reduced barrier properties against moisture intrusion if the crystalline content of the thicker film is too high. Balancing such concerns, film thicknesses in the range from about 80 nm to about 3000 nm, preferably about 150 nm to about 2000 nm, even more preferably about 150 nm to about 1000 nm would be suitable. Film thicknesses of 200 nm and 400 nm, respectively, would be particularly suitable for hybrid SnO₂ films or fluorine-doped SnO₂ (F—SnO₂) films.

Barrier films of the present invention can be formed in a variety of ways. In illustrative modes of practice, the films are deposited onto the desired substrate using suitable deposition technique(s). Physical vapor deposition techniques are preferred. RF magnetron sputtering techniques are particularly preferred, as the process conditions can be readily tuned to control the hybrid morphology.

In an exemplary RF magnetron sputtering process, the substrate to be coated is provided at a suitable temperature. If the temperature is too low, the crystalline content of the resultant barrier film may be too low to provide desired conductivity characteristics. If the temperature is too high, the crystalline content of the resultant film may be too high, compromising moisture barrier properties. Balancing such concerns, exemplary substrate temperatures may be in the range from −20° C. to 250° C., preferably 0° C. to 150° C. In exemplary embodiments, substrates at 100° C. and room temperature, respectively, would be suitable for films formed from SnO₂. Substrates often are incubated at the desired temperature for a suitable incubating period prior to beginning sputtering. For instance, suitable incubation periods may be 1 minute or longer. For throughput reasons, incubation periods are usually less than 24 hours, preferably less than 4 hours, more preferably less than 1 hour. In an exemplary mode of practice, a substrate is incubated at 150° C. for ten minutes prior to starting deposition.

It can be appreciated that the temperature is one factor that impacts the relative amounts of amorphous and crystalline content of the resultant film. Accordingly, temperature is a convenient parameter that can be varied to tune the amorphous and crystalline morphology. If more crystalline content is desired, a higher substrate temperature can be used. If less crystalline content is desired, a lower substrate temperature can be used. In some modes of practice, the substrate temperature is generally maintained at a constant temperature during the deposition to provide a film in which the crystalline domains are substantially uniformly distributed throughout the bulk volume of the film. In other modes of practice, the temperature can be increased or decreased as the film grows to adjust the morphology and thereby grade the crystalline content of the resultant film.

The RF power level used to accomplish sputtering also can be selected from a wide range of power levels. Lower power levels are more preferred as these generate less heat and provide a lower deposition flux. Higher density, better quality barrier films also result when lower power levels are used. Like temperature, RF power level can also be used to tune the relative amounts of amorphous and crystalline content in the resultant films. Generally, lower power levels provide less crystalline content, while higher power levels tend to provide higher crystalline content. In illustrative modes of practice, RF power levels desirably are in the range from about 50 W to about 350 W. In particular embodiments, RF power levels of 100 W, 150 W, and 250 W would be suitable. For a target that is approximately 3 inches in diameter. Power levels can be scaled up or down for targets with larger or smaller areas, respectively.

Single or multiple targets can be used for RF magnetron sputtering. If a film is to include only a single kind of material, a single target is conveniently used. For instance, SnO₂ targets are useful for depositing SnO₂ films. If a film is to include multiple kinds of materials, single targets containing the materials or multiple respective targets may be used. For instance, an indium tin oxide film (ITO) can be sputtered using an In₂O₃ target doped with 10% SnO₂.

Targets desirably are cleaned prior to a deposition. This can be accomplished by shielding the substrate as the target is pre-sputtered for a suitable time period. Suitable time periods may be in the range from 1 second to 20 minutes, preferably 30 seconds to 10 minutes. In one mode of practice, cleaning occurred by pre-sputtering a SnO₂ target for 3 minutes.

One or more sputtering guns can be aimed at a suitable angle toward the target(s) to accomplish sputtering. Often, the angle is recited as the angle with respect to an axis that is normal to the substrate surface. In one mode of practice, sputtering guns were at a 23.58 degree angle (relative to the substrate normal) to accomplish sputtering of a SnO₂ target.

Prior to sputtering or pre-sputtering, a suitable base pressure is typically established, and the deposition is initiated after the base pressure or lower is reached. In exemplary embodiments, the base pressure may be on the order of about 10⁻⁴ Torr or less, preferably 10⁻⁵ Torr or less, more preferably 10⁻⁶ Torr or less. In one mode of practice, a base pressure of 2×10⁻⁶ Torr or less would be suitable.

After the base pressure is reached, pre-sputtering and then sputtering may occur at any suitable operating pressure(s). Exemplary operating pressures are in the range from about 1 to about 300 mTorr, preferably about 1 mTorr to about 100 mTorr. In one mode of practice, an operating pressure of about 5 mTorr would be suitable.

The operating pressure conveniently is established and maintained by flowing one or more suitable sputtering gases through the sputtering chamber. Exemplary sputtering gases include Ar, O₂, H₂, N₂, combinations of these and the like. In one mode of practice, a flow of 20 sccm Ar would be suitable to establish an operating pressure of 5 mTorr.

Dopants may be introduced in multiple ways using a wide range of techniques well known in the industry. For example, the target itself may be doped. Flourine-doped SnO₂ targets are commercially available, as one example. Dopant source(s) also may be provided in the form of one or more separate targets. As still yet another option, evaporated fluidized material or gas (i.e. CF₄, SF₆, etc) may be introduced into the chamber generating the desired doping level in the film.

Barrier films of the present invention may be incorporated into a wide range of passive and active optoelectronic devices. Examples of such devices include antistatic films, antireflective stacks, electromagnetic shielding, heat-efficient electrochemical windows, electrochromic windows, electroluminescent lamps, liquid crystal and other flat panel displays, light emitting diodes, laser diodes, transparent membrane switches, touch screens, sensors, and photovoltaic devices. Exemplary photovoltaic devices include thin film organic and/or inorganic solar cells as well as non-thin film cells.

In preferred modes of practice, barrier films of the present invention are used as protective coatings for photovoltaic devices. The barrier films can be incorporated into such devices at one or more locations between the absorber layer(s) and the light incident face of the device. Alternatively, the barrier films can be incorporated into such devices at one or more locations between the absorber layer(s) and the backside face of the device.

A typical photovoltaic device generally comprises at least one absorber layer sandwiched between two electrodes. At least one electrode is transparent to allow incident light to reach the absorber layer. An electrically conductive grid is usually deposited on top of the transparent electrode to allow electric coupling to external circuitry. In particularly preferred modes of practice, the barrier films are coated over the electric grid to protect the grid and underlying layers against moisture. Advantageously, the barrier films conform readily to the undulating topography of the grid and exposed device surfaces between the grid wires with minimal if any cracking or other defects at surface junctures. This protects the grid against corrosion. The barrier films are particularly beneficial for use in CIGS devices as CIGS absorbers are sensitive to moisture.

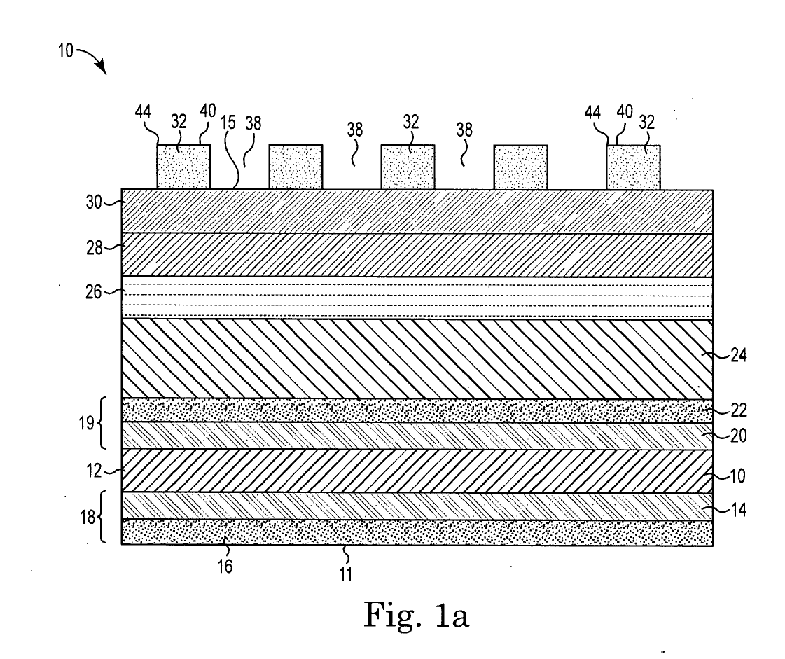

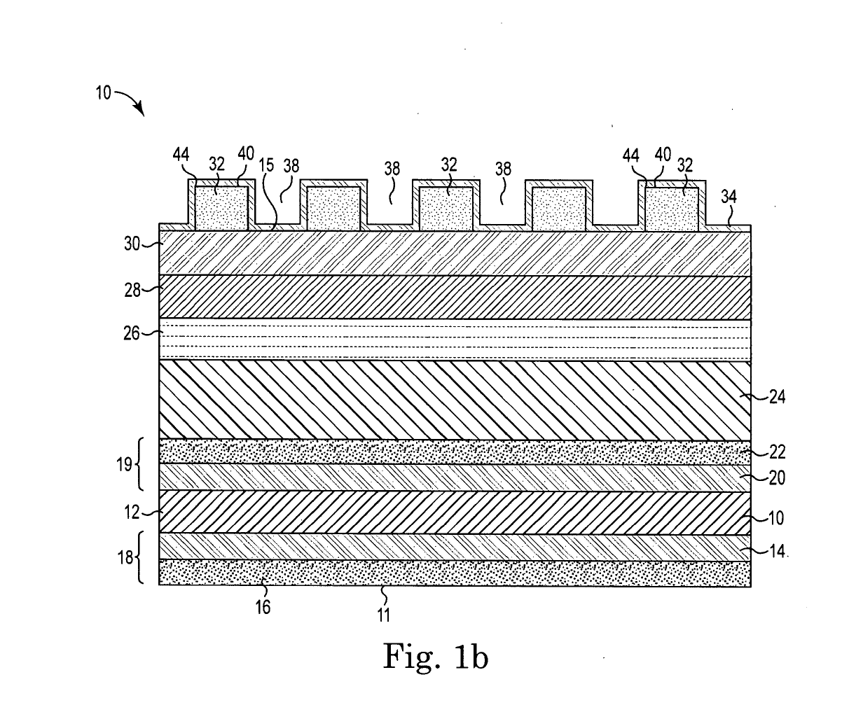

An exemplary photovoltaic device 10 of the present invention is shown in FIG. 1a. Photovoltaic device 10 incorporates a suitable support 12 on which the other layers and features are fabricated. Such a support may be rigid or flexible, but desirably is flexible in those embodiments in which the device may be used in combination with non-flat surfaces. Support may be formed from a single or multiple layers formed from a wide range of materials. These include glass, quartz, other ceramic materials, polymers, metals, metal alloys, intermetallic compositions, paper, woven or non-woven fabrics, combinations of these, and the like. Stainless steel is preferred in many embodiments.

One or more electrical conductors are incorporated into device 10 for the collection of current generated by the photoactive structure. A wide range of electrical conductors may be used. Generally, electrical conductors are respectively included both proximal to the backside 11 as well as to the light incident side 15 of the device 10 in order to complete the desired electric circuit. Proximal to the backside 11, for example, backside electrical contact region 18 provides a backside electrical contact in representative embodiments. Proximal to the light incident side 15 in representative embodiments, a typical device 10 incorporates a transparent conductive layer 30 and a collection grid 32.

The backside contact region 18 may have a single or multiple layer construction. Region 18 may be formed from a wide range of electrically conductive materials, including one or more of Cu, Mo, Ag, Al, Cr, Ni, Ti, Ta, Nb, W combinations of these, and the like. For purposes of illustration, backside electrical contact region 18 has a dual layer construction in which layer 14 is formed from a material such as Cr, and layer 16 is formed from a suitable material such as Mo.

The interface between the support 12 and the absorber region 24 is enhanced by region 19 that provides many functions. As one, 19 helps to isolate the absorber region 24 from the support to minimize migration of support constituents into the absorber material. Additionally, region 19 can help to block the migration of Fe and Ni constituents of a stainless steel support into the absorber region 24. The region 19 also can protect the support 12 such as by protecting against Se if Se is used in the formation of absorber region 24. Region 19 also can enhance adhesion of the absorber region 24 to the underlying structure. The surface 21 of region 19 proximal to the absorber region 24 also can serve as a template for crystalline growth.

Region 19 can have a single layer or multilayer construction. As shown, region 19 includes layers 20 and 22. These layers 20 and 22 may independently be formed from a wide range of materials, including the materials used to form layers 14 and/or 16. In one embodiment, layer 20 includes Cr, and layer 22 includes molybdenum.

Absorber region 24 generally incorporates one or more semiconductor materials that exhibit the photoelectric effect. These materials convert incident light energy into electrical energy. Exemplary photoelectrically active semiconductor materials include monocrystalline silicon, polycrystalline silicon, amorphous silicon, cadmium telluride, gallium arsenide, copper oxide, zinc phosphide, organic photovoltaic materials, CIGS materials incorporating copper and indium such as copper indium gallium selenide/sulfide and/or copper indium gallium selenide/sulfide, combinations of these, and the like. As used herein the term “CIGS material” refers generally to the photoelectrically active compositions including at least one of Se, S, and/or Te, and two or more metals including at least copper and indium.

Among these semiconducting materials, CIGS materials are particularly susceptible to moisture damage. Advantageously, CIGS-based absorber regions 24 maintain performance and have significantly extended service life when protected by barrier films of the present invention.

One preferred class of CIGS materials useful in absorber region 24 may be represented by the formula

CuₐIn_{b}Ga_{c}Al_{d}Se_{w}SₓTe_{y}Na_{z} (A)

wherein, if “a” is defined as 1, then:

“(b+c+d)/a”=1 to 2.5, preferably 1.05 to 1.65

“b” is 0 to 2, preferably 0.8 to 1.3

“c” is 0 to 0.5, preferably 0.05 to 0.35

d is 0 to 0.5, preferably 0.05 to 0.35, preferably d=0

“(w+x+y)” is 1 to 3, preferably 2 to 2.8

“w” is 0 or more, preferably at least 1 and more preferably at least 2 to 3

“x” is 0 to 3, preferably 0 to 0.5

“y” is 0 to 3, preferably 0 to 0.5

“z” is 0 to 0.5, preferably 0.005 to 0.02

The copper indium selenides/sulfides and copper indium gallium selenides/sulfides are preferred. Strictly stoichiometric illustrative examples of such photoelectronically active PACB materials may be represented by the formula

CuIn₍₁₋ₓ₎GaₓSe_{(2-y)}S_{y} (B)

where x is 0 to 1 and y is 0 to 2. As measured and processed, such films usually include additional In, Ga, Se, and/or S. Corresponding precursors of such PACB materials generally would include constituents in the same proportions as specified in Formula A or B, including additional In and/or Ga as applicable to compensate for In loss during post-chacogenization, except that the chalcogen content is sub-stoichiometric in the precursor.

A buffer layer 26 may be formed over the absorber region 24. The use of buffer region 26 has been shown to enhance the electronic performance of photovoltaic devices. In some embodiments where absorber region 24 comprises a p-type absorber material, buffer region 26 generally comprises an n-type semiconductor material with a suitable band gap to help form a p-n junction or otherwise enhance the electrical interface between the absorber region 24 and overlying electrical contacts. Suitable band gaps for a typical buffer region 26 generally are in the range from about 1.7 eV to about 4.0 eV. Tin oxide, for example, may have a band gap in the range from 3.6 eV to 3.8 eV. Illustrative embodiments of buffer region 26 generally may have a thickness in the range from about 5 nm to about 200 nm.

A wide range of n-type semiconductor materials may be used to form buffer region 26. Illustrative materials include selenides, sulfides, and/or oxides of one or more of cadmium, zinc, lead, indium, tin, combinations of these and the like, optionally doped with materials including one or more of fluorine, sodium, combinations of these and the like. In some illustrative embodiments, the buffer region is a selenide and/or sulfide including cadmium and optionally at least one other metal such as zinc. Other illustrative embodiments would include sulfides and/or selenides of zinc. Additional illustrative embodiments may incorporate oxides of tin doped with material(s) such as fluorine. Buffer layer technology is further described in D. Hariskos, et al, “Buffer layers in Cu(In,Ga)Se2 solar cells and modules,” Thin Solid Films, 2005, 480-481, 99-109; C. Platzer-Bjorkman, et al, “Zn(O,S) Buffer Layers by Atomic Layer Deposition . . . ” Journal of Applied Physics, 2006, 100, 044506; U. Malm, et al, “Determination of dominant recombination paths . . . ”, Thin Solid Films, 2005, 480-481, 208-212; and Y. Kim, et al, “Studies on Polycrystalline ZnS thin films . . . ” Applied Surface Science, 2004, 229, 105-111.

Optional window layer 28 is formed over the buffer region 26. The window layer 28 in some embodiments may help to protect against shunts. The window region also may protect the underlying photoactive layers during subsequent deposition of a transparent conductive layer or other electrically conductive layer(s). Window layer 28 also may function as a current homogenizer.

The window region may be formed from a wide range of materials and often is formed from a resistive, transparent oxide such as an oxide of Zn, In, Cd, Sn, combinations of these and the like. An exemplary window material is intrinsic ZnO. A typical window region may have a thickness of at least about 10 nm, preferably at least about 50 nm, more preferably at least about 80 nm. Desirably, the window region has a thickness that is less than about 200 nm, preferably less than about 150 nm, more preferably less than about 120 nm.

Transparent conductive layer 30 is generally formed as a top contiguous active layer over the buffer or window layers in many embodiments. In many suitable embodiments, the transparent conductive layer 30 has a thickness in the range from about 5 nm to about 1500 nm, preferably about 150 nm to about 200 nm. As shown, the transparent conductive layer 30 is in contact with the window region 28. As an example of another option, transparent conductive layer 30 might be in direct contact with the buffer region 26. One or more other kinds of intervening layers optionally may be interposed for a variety of reasons such as to promote adhesion, enhance electrical performance, or the like.

The transparent conductive layer 30 may be a very thin metal film (e.g., a metal film having a thickness in the range from about 5 nm to about 200 nm, preferably from about 30 nm to about 100 nm, in representative embodiments so that the resultant films are sufficiently transparent to allow incident light to reach the absorber region 24). As used herein, the term “metal” refers not only to metals, but also to metal admixtures such as alloys, intermetallic compositions, combinations of these, and the like. These metal compositions optionally may be doped. Examples of metals that could be used to form thin, optically transparent layers 30 include the metals suitable for use in the backside contact region 24, combinations of these, and the like.

As an alternative to metals or in combination with metals, a wide variety of transparent conducting oxide (TCO) materials or combinations of these may be incorporated into the transparent conductive layer 30. Examples include fluorine-doped tin oxide, tin oxide, indium oxide, indium tin oxide (ITO), aluminum doped zinc oxide (AZO), zinc oxide, combinations of these, and the like. In one illustrative embodiment, the transparent conductive layer 30 is indium tin oxide. TCO layers are conveniently formed via sputtering or other suitable deposition technique.

Electrically conductive collection grid 32 can be formed from ingredients that include a wide range of electrically conducting materials, but most desirably are formed from one or more metals, metal alloys, or intermetallic compositions. Exemplary contact materials include one or more of Ag, Al, Cu, Cr, Ni, Ti, combinations of these, and the like. In one illustrative embodiment, the grid 32 has a dual layer construction (not shown) comprising nickel and silver. A first layer of Ni is deposited to help enhance the adhesion of a second layer of Ag to the underlying transparent conductive layer 30.

FIG. 1b shows how a barrier film 34 of the present invention can be incorporated into device 10 of FIG. 1a. Barrier film 34 of the present invention is deposited over the grid 32 and transparent conductive layer 30. Barrier film 34 readily conforms to the undulating topography of the surfaces on which film 34 is formed. Barrier film 34 protects the underlying materials against moisture intrusion. Barrier film 34 desirably has suitable electrical conductivity to allow grid 32 to be electrically coupled to external circuitry (not shown). Barrier film 34 has a composition and hybrid morphology features as described above. In preferred embodiments, barrier film 34 is formed from at least one of SnO₂, doped SnO₂, indium tin oxide, combinations of these, and the like.

In many embodiments, film 34 has a thickness on the order of about 2 micrometers or less, even about 1 micrometer or less, an even on the order of about 100 nm to 200 nm. Advantageously, the barrier film 34 in the form of such thin films provides outstanding protection against moisture egress. The ability of films of such modest thickness to provide such a high degree of moisture protection is quite unexpected but very beneficial, particularly in embodiments that also possess high levels of electrical conductivity.

Optionally, one or more additional barrier layers (not shown) can be formed over barrier film 34 to further enhance the protection of device 10. Because barrier film 34 provides such an excellent barrier against moisture, the demand upon the additional, optional barrier layers (if any) to protect against moisture is significantly eased. Accordingly, these additional layers need not provide a high level of moisture protection and can be selected to provide other kinds of protection, e.g., protection against oxygen, abrasion, static and dynamic load resilience (i.e., hail impact) and the like. With eased concerns for moisture protection, the range of materials that can be selected for these additional barrier layers is expanded. Exemplary materials that can be used in such additional barrier layers include one or more fluoropolymers, ethylene vinyl acetate copolymer (EVA), polyolefins, silicones, mica, glass, combinations of these and the like.

FIG. 1b shows how the barrier film 34 conforms to the topography of the surface on which film 34 is deposited. The surface is nonplanar and includes basin regions 38 defined by layer 30 and the walls of grid 32. Raised plateau regions 40 are formed by the top surfaces of grid 32. Consequently the surface on which film 34 is formed comprises a plurality of junctures 42 and 44. In this embodiment, the junctures 42 and 44 are defined by the first and second electrode features (layer 30 and grid 32, respectively). Junctures 42 and 44 are formed at boundaries where the surface portions meet and change direction abruptly. Junctures 42 are inside corners of basin regions 38 while junctures 44 are outside corners between basin regions 38 and plateau regions 40. Note how the barrier film 34 follows the contours and thereby mimics the topography of the basins 38 and plateaus 40.

Surprisingly, the thin barrier film 34 conforms to the underlying topography and yet provides long-lasting, high quality barrier protection. It is surprising that thin film, conforming coatings with crystalline content can be formed, with these durability characteristics. Generally, thin, conforming, crystalline films have serious quality problems, particularly at junctures where different planes of crystalline material attempt to merge. One film portion grows in one plane, while another portion grows in a different plane. The two growing crystalline masses generally do not merge effectively at junctures. Consequently, resultant films display poorly integrated grain boundaries, undesirable cracking, loss of adhesion, or other serious defects at junctures. The low quality grain boundaries, gaps, or cracks undesirably provide a pathway for moisture to penetrate the barrier and cause degradation of the device.

In contrast to crystalline materials, hybrid compositions having crystalline content dispersed in an amorphous matrix are able to meld together much more homogeneously and cohesively. Defects at junctures are dramatically reduced, contributing to long lasting barrier properties.

In addition to protecting against moisture, barrier film 34 has many additional advantages. Because film embodiments of the present invention can provide excellent moisture protection even when provided as thin films having thicknesses on a nanometer scale (e.g., about 2000 nm or less in thickness), the films can be incorporated into flexible optoelectronic devices. The device 10 is preferably flexible. In one embodiment, the device 10 could also be sufficiently flexible to be wound for continuous roll-to-roll manufacturing for lower cost manufacturing without damage to the structure or any of its layers. Preferably, the device can be so wound on a core of about at least 1 meter diameter, more preferably a core of at least 0.5 meter diameter, and most preferably on a core of at least 0.3 meter diameter. Flexibility characteristics are determined at 25° C. This allows rigid encapsulation strategies, e.g., rigid glass encapsulation to be avoided if desired. Exemplary flexible devices include the DOW POWERHOUSE™ solar shingle product available from The Dow Chemical Company, Midland, Mich.

In some embodiments, device 10 according to any of FIG. 1a, 1b, or 1c is flexible. In preferred embodiments, the term “flexible” with respect to device 10 means that the device can be wound on a core having a round cross-section with a minimum diameter of 1 meter, preferably a minimum diameter of 0.5 meter, and more preferably a minimum diameter of 0.3 meter.

The present invention will now be described with regard to the following illustrative examples.

### Example 1

CIGS solar cells having the structure shown in FIG. 1a were fabricated. Support 12 was a stainless steel foil. Layers 14 and 16 were formed from Cr and Mo respectively. Backside contact region 18 included Cr layer 14 and molybdenum layer 16. Absorber region 24 was formed from CIGS material by co-evaporation of Cu, In, Ga, and Se and was approximately 2 μm thick. Following, 40 nm thick CdS was deposited on the CIGS film as buffer region 26 through chemical bath deposition. A 50 nm thick insulating layer of ZnO as window layer 28 and a 150 nm thick transparent conducting oxide layer of indium tin oxide (ITO) as layer 30 were deposited on the CdS by RF magnetron sputtering. Contact to the ITO was made with an evaporated Ni/Ag grid pattern as grid 32 that is connected to a thicker bus bar (not shown) at the edge of the foil 12 for electrical contact.

Transmission electron microscopy (TEM) analysis was conducted using an FEI Tecnai F-30 microscope with a Schottky field-emission electron gun operated at 300 keV. See, e.g., M. J. Behr, K. A. Mkhoyan, E. S. Aydil, Orientation and morphological evolution of catalyst nanoparticles during carbon nanotube growth, ACS Nano 4 (2010) 5087-5094. The entirety of this technical article is incorporated herein by reference for all purposes.

Two kinds of cell sample sets were prepared from these CIGS solar cells. In one set of the samples, SnO₂ was deposited to provide barrier films as shown in FIG. 1(b). For the second sample set, CIGS solar cells without any SnO₂ barrier films as shown in FIG. 1(a) were used as control samples for comparison. These cells are referred as the control solar cells in these examples. In the first set of samples, there were 5 substrates and one cell per substrate was measured, totaling 5 cells.

To prepare the samples including barrier films, tin dioxide thin films with varying thickness were deposited on the CIGS solar cells using RF magnetron sputtering. 99.99% stoichiometric SnO₂ targets were used. The film thickness was varied between 200 nm±20 nm and 500 nm±20 nm. The films were deposited at the RF power levels, 100 W, 150 W, and 250 W and at two different substrate temperatures, room temperature and 150° C. For the films deposited at 150° C., the substrates were kept at 150° C. for 10 minutes before starting the deposition. Prior to all depositions, the target surface was cleaned for 3 minutes by pre-sputtering while a shutter protected the substrate. The base pressure in the sputtering chamber was 2×10⁻⁶ Torr and deposition sequence was started only after reaching this pressure or lower for each experiment. The sputtering pressure was kept constant at 5 mTorr, which was maintained by flowing 20 sccm of sputtering gas (Ar) into the chamber. The sputtering guns were at a 23.58° with respect to the substrate normal.

### Example 2

Both sets of samples prepared in Example 1 were subject to damp heat testing to assess the ability of the barrier films to protect the cells against moisture. The damp heat tests were conducted in a temperature and humidity controlled chamber at 85° C. and 85% relative humidity. The solar cells were taken out from the test chamber every 24 hours and their current-voltage characteristics were measured. The control solar cells were tested under damp-heat conditions for 168 hours, while the SnO₂-film-coated cells were tested under identical conditions for 240 hours. The current-voltage characteristics of the solar cells were recorded periodically under 100 mW/cm² (AM 1.5) illumination generated by a solar simulator equipped with a Xe-arc lamp. The fill factor (FF), the open circuit voltage (V_{oc}), the short circuit current density (J_{sc}), and the cell efficiency (represented by the symbol η and given by the expression η=FF·J_{sc}·V_{oc}) were measured outside the damp-heat test chamber under ambient conditions (about 25° C.). The shunt (Rₛₕ) and the series (Rₛᵣ) resistances of the cells also were determined as a function of the damp-heat test exposure time.

### Example 3

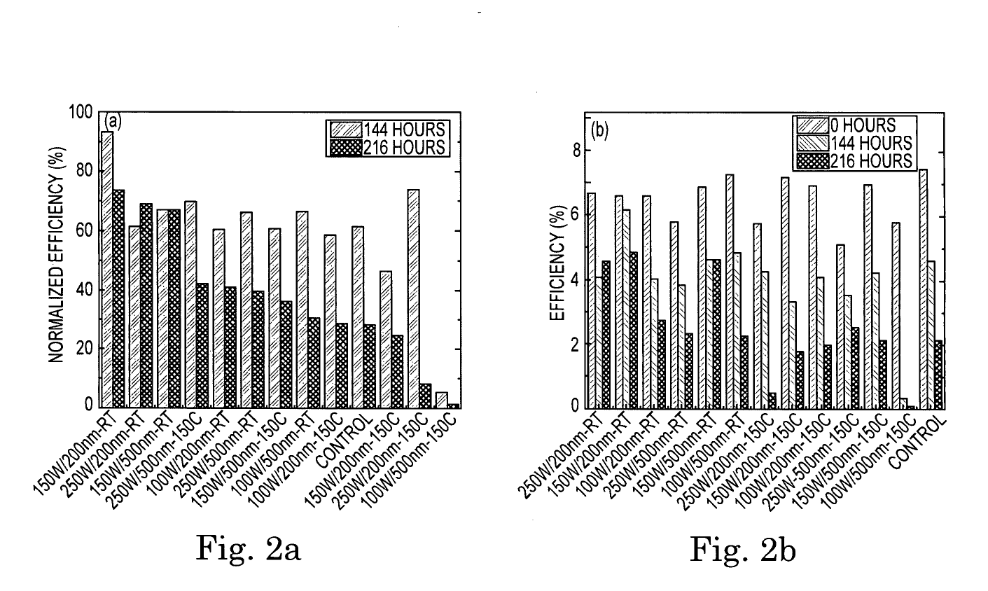

This example reports the data obtained in Example 2 for the first set of sample solar cells for which the SnO₂ films were deposited on completed solar cells having a structure according to FIG. 1b. FIGS. 2a and 2b show the results from the first set of experiments. The SnO₂ films were deposited under twelve different sputtering conditions reported in the Figures.

FIG. 2(a) shows the efficiency of the solar cells, normalized to their initial efficiency, after 144 and 216 hours of damp-heat testing. FIG. 2(b) shows the absolute values of the efficiencies after 144 and 216 hours in the damp-heat testing chamber. The results are also compared with the unprotected CIGS solar cells, named as “Control” in FIGS. 2(a) and 2(b).

The data show that SnO₂ films help increase the damp-heat durability of the CIGS solar cells. A significant fraction of the SnO₂-coated cells performed better than the control samples after 216 hours in the damp-heat test chamber.

Additionally, the solar cells coated with SnO₂ films sputtered at room temperature showed better durability than the solar cells coated with SnO₂ sputtered at 150° C. For example, the top three films in FIG. 2(a) were all deposited at room temperature and retain approximately 70% of their initial efficiency as compared to the control solar cell whose efficiency has decayed to 30% of the initial value. The solar cell coated with 200 nm thick SnO₂ film deposited using 150 W RF plasma power at room temperature showed the best reliability. The SnO₂ films deposited at room temperature were a mixture of amorphous SnO₂ and nanocrystalline SnO₂ with nanometer size grains embedded in an amorphous matrix (semicrystalline). In contrast, the SnO₂ films deposited at 150° C. were polycrystalline with crystal grains abutted against each other. Accordingly, without wishing to be bound, the better protection performance of the semicrystalline films deposited at room temperature compared to polycrystalline films deposited at 150° C. is attributed to the lack of continuous crystalline grain boundaries and therefore lack of the diffusion of water through the grain boundaries. The deposition conditions of the SnO₂ thin films for the solar cells of the second sample set are given in Table 1.

TABLE 1
SnO₂ deposition conditions for the first set of solar cells

| | SnO₂ Deposition Conditions | | |
|---|---|---|---|
| | | | Thickness of |
| | RF Power | Temperature of | SnO₂ film |
| Solar Cell Sample Name | (Watts) | Substrate (° C.) | (nm) |
| 250 W-200 nm-RT | 250 | Room temperature | 200 |
| 150 W-200 nm-RT | 150 | Room temperature | 200 |
| 100 W-200 nm-RT | 100 | Room temperature | 200 |
| 250 W-500 nm-RT | 250 | Room temperature | 500 |
| 150 W-500 nm-RT | 150 | Room temperature | 500 |
| 100 W-500 nm-RT | 100 | Room temperature | 500 |
| 250 W-500 nm-150 C. | 250 | 150 | 500 |
| 150 W-500 nm-150 C. | 150 | 150 | 500 |
| 250 W-200 nm-150 C. | 250 | 150 | 200 |
| 150 W-200 nm-150 C. | 150 | 150 | 200 |
| 150 W-500 nm-150 C. | 150 | 150 | 500 |
| 100 W-200 nm-150 C. | 100 | 150 | 200 |
| Control | 0 | 0 | 0 |
| Control | 0 | 0 | 0 |

### Example 4

FIG. 3 shows low- and high-resolution TEMs of SnO₂ films deposited under the same deposition conditions as used in Example 1 at room temperature using a sputtering power of 150 W. A SiO₂-covered Si substrate was used for deposition of SnO₂ films having thicknesses of 200 and 500 nm. The semicrystalline nature of the SnO₂ film is apparent. The TEM images show nanocrystalline SnO₂ grains embedded in an amorphous SnO₂ matrix. In these hybrid films, there are little if any continuous grain boundaries to facilitate water diffusion. Note that the crystalline grains are substantially homogeneously distributed throughout the amorphous matrix. The TEM images indicate that the crystalline grains are randomly oriented. The crystals as shown in FIG. 3 range in size from 2 nm to 10 nm in diameter. Based on the sizes of the crystalline grains and the thickness of the film, it is estimated that the fraction of the crystalline grains is 25-30% of the total barrier film. In contrast, films deposited at 150° C. tended to be more crystalline with grains abutted against each other.

In the TEM image, the arrangement of dots can be used to visually assess morphology. Note how the arrangement of dots in the Si layer is highly ordered. The dots are ordered in rows and arrays of rows. This evidences the crystalline morphology of the Si layer. In contrast, the dots in the SnO₂ layer are randomly distributed. Although localized regions may include some order, each ordered region is a small portion of the whole cross section and ordered regions generally do not repeat. There are also regions in which there is no apparent order. In many instances, note how locally ordered regions are isolated from other locally ordered regions.

FIG. 3 also shows a Bragg diffraction pattern for the SnO₂ film. The circular, diffuse ring is further evidence the amorphous character of the film. If the film were to have had more substantially crystallinity, the Bragg diffraction would show a grid of dots as evidence of a crystal lattice or multiple concentric ring patterns formed by closely spaced dots around circles.

### Example 5

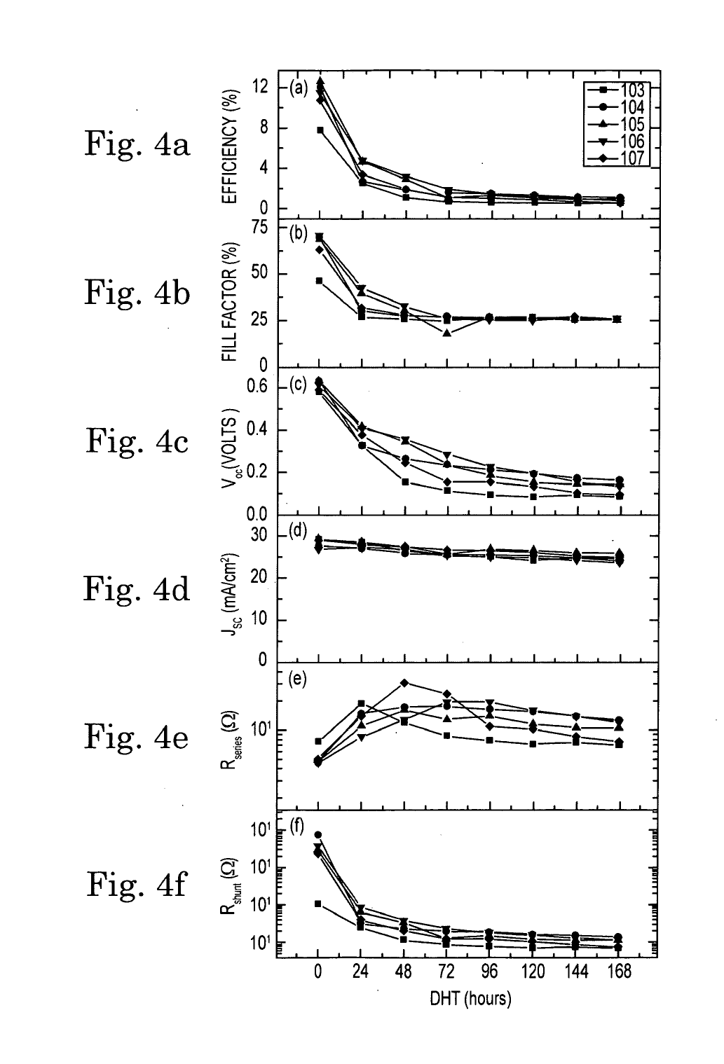

FIGS. 4a through 4f show the changes in the power conversion efficiency, fill factor, open circuit voltage, and short circuit current density as well as the changes in the shunt and series resistances as a function of damp-heat testing time for the unprotected control solar cells of the third sample set. Five substrates were used and each substrate had eight solar cells (40 cells total). The average results of these devices are shown in FIGS. 4a through 4f. FIG. 4a shows that the power conversion efficiencies of the unprotected solar cells decreased rapidly from 8-12% to less than 3% within 48 hours as a function of damp-heat test time. Similarly, the fill factor for these control cells decreased within 48 hours from ˜70% to ˜25% according to FIG. 4b. FIG. 4(c) shows the evolution of the open circuit voltage of these control solar cells as a function of damp-heat test time. The open circuit voltage dropped by approximately 50% from ˜0.65 V in the first 24-48 hours and then decayed more slowly to ˜0.12 V. FIG. 4(d) shows that the short circuit current density, J_{sc}, only lost 10% of its initial value, a noticeable but otherwise insignificant decrease when compared to other solar cell figures of merit. FIGS. 4(e) and 4(f) show the evolution of the series and the shunt resistances, respectively, as a function of damp-heat test time. The series resistance increased from ˜5Ω to 10-30Ω within the first 48 hours but eventually saturated at approximately 10±2Ω after 168 hours of DH exposure. More dramatic changes in the shunt resistance were observed. The shunt resistance decreased exponentially with damp-heat testing time by three orders of magnitude during the first 72 hours and saturated after reaching approximately 5Ω to 20Ω.

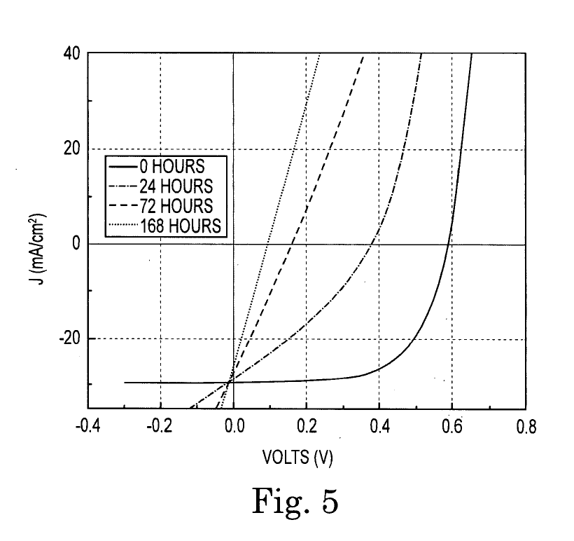

FIG. 5 shows the evolution of the current-voltage (J−V) characteristics of a typical control solar cell. The fill factor decreases without a significant drop in the J_{sc} and the J−V characteristic degrades by pivoting around (0, J_{sc}) point. This shows that the dramatic drop in the shunt resistance is responsible for the decrease in the fill factor and the effect of the changing series resistance is small in comparison. The increase in series resistance is attributed to the increase in ZnO and ITO resistivity.

The penetration of water to the CIGS absorber layer is believed to decrease the carrier concentration in the CIGS layer and to increase the Fermi level in the p-type absorber, E_{FP}. The increase in E_{FP} explains the decrease in open circuit voltage. In addition, the carrier concentration in the ZnO layer may also be decreasing which lowers the Fermi level, E_{FN}, in the n-type ZnO and therefore the open circuit voltage. Decrease in carrier concentration and carrier mobility has been observed previously in ITO films. Lower carrier concentration in CIGS can also increase series resistance of the solar cell and contribute to the decrease in the fill factor.

### Example 6

This example reports overall conclusions made with respect to the information developed in Examples 1 through 5. Compared to uncoated control CIGS solar cells, the damp-heat durability of SnO₂-coated CIGS solar cells increased significantly when the protective coating included a hybrid morphology according to principles of the present invention. Specifically, the power conversion efficiency, the fill factor, and the open circuit voltage of the uncoated control solar cells decreased dramatically during damp-heat tests while their power conversion efficiencies dropped from ˜12% to ˜0.8% in 168 hours. Consistent with previous reports, the decrease in the efficiency was caused by decreasing fill factor and open circuit voltage. The short circuit current density did not change significantly. In contrast, the solar cells protected with a hybrid SnO₂ over-layer deposited at room temperature maintained their initial power conversion efficiencies even after 240 hours in the damp-heat test chamber at 85° C. and 85% relative humidity. In all SnO₂-coated solar cells, the short circuit current density and the open circuit voltage decreased less than 8% even after 240 hours of damp-heat testing. Any observed decline in the power conversion efficiency is attributed mostly to decreasing fill factor. The best damp heat test protection was achieved with hybrid SnO₂ films sputtered at room temperature using 150 W RF power. Even a SnO₂ film as thin as 200 nm thick is able to improve the damp heat stability of CIGS solar cells significantly. The semicrystalline structure of the hybrid SnO₂ layers, lacking substantially continuous grain boundaries, is believed to be at least one factor that inhibits moisture penetration. This hybrid structure protects against diffusion of water molecules along grain boundaries and provides a better protection from damp-heat conditions than polycrystalline films.

The complete disclosures of the patents, patent documents, technical articles, and other publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

1. An optoelectronic device comprising:
(a) a surface having a nonplanar topography; and
(b) a conformal barrier coating provided on the surface in a manner effective to conform to said nonplanar topography, wherein the barrier coating comprises discrete, inorganic, crystalline domains dispersed in an inorganic amorphous matrix.

2. The optoelectronic device of claim 1, wherein the device comprises an electronic grid electrically coupled to a transparent electrode layer, wherein at least portions of the electronic grid and the transparent electrode layer define at least a portion of the surface on which the conformal barrier coating is provided.

3. The optoelectronic device of claim 1, wherein the device comprises an absorbing region that comprises a photoelectrically active material comprising copper and indium.

4. The optoelectronic device of claim 1, wherein the surface has a topography comprising a plurality of basin regions, raised plateau regions, and wall regions.

5. The optoelectronic device of claim 1, wherein the surface comprises a plurality of junctures provided at least in part by at least one first electrically conductive feature and at least one second electrically conductive feature.

6. The optoelectronic device of claim 1, wherein the conformal barrier coating comprises an oxide of tin that optionally is doped with fluorine.

7. The optoelectronic device of claim 1, wherein the conformal barrier coating has a volume percent ratio of amorphous content to crystalline content in the range from 1:2 to 100:1.

8. The optoelectronic device of claim 1, wherein the conformal barrier coating has a volume percent ratio of amorphous content to crystalline content in the range from 1:1 to 10:1.

9. The optoelectronic device of claim 1, wherein at least 30 volume percent of the crystalline domains of the barrier coating have a size in the range from 2 nm to 10 nm.

10. The optoelectronic device of claim 1, wherein the barrier coating has a resistivity of 10⁻¹ Ohm-cm or less.

11. The optoelectronic device of claim 1, wherein the barrier coating has a light transmittance from 300 nm to 1400 nm as deposited of at least 75%.

12. The optoelectronic device of claim 1, wherein the barrier coating has a thickness in the range from 150 nm to 1000 nm.

13. A method of making an optoelectronic device, comprising the steps of:
(a) providing an optoelectronic substrate comprising a photoelectrically active region, at least first and second electrode layers electrically coupled to the photoelectrically active region wherein at least the first electrode layer is at least partially transparent to visible light, and an electrically conductive grid electrically coupled to the first electrode layer, and wherein the first electrode layer and the electrically conductive grid define a nonplanar surface;
(b) forming a conforming inorganic, barrier coating on the nonplanar surface, wherein the barrier coating comprises discrete, inorganic, crystalline domains dispersed in an inorganic amorphous matrix.

14. The method of claim 13, wherein the forming step comprises sputtering one or more targets onto the surface, wherein at least one of said targets comprises an oxide of tin, and wherein the surface is at a temperature of 150° C. or less.

15. The optoelectronic device of claim 2, wherein the device comprises an absorbing region that comprises a photoelectrically active material comprising copper and indium.

16. The optoelectronic device of claim 2, wherein the conformal barrier coating comprises an oxide of tin that optionally is doped with fluorine.

17. The optoelectronic device of claim 2, wherein the conformal barrier coating has a volume percent ratio of amorphous content to crystalline content in the range from 1:2 to 100:1.

18. The optoelectronic device of claim 16, wherein the conformal barrier coating has a volume percent ratio of amorphous content to crystalline content in the range from 1:2 to 100:1.

19. The optoelectronic device of claim 2, wherein the conformal barrier coating has a volume percent ratio of amorphous content to crystalline content in the range from 1:1 to 10:1.

20. The optoelectronic device of claim 16, wherein the conformal barrier coating has a volume percent ratio of amorphous content to crystalline content in the range from 1:1 to 10:1.
